(19) United States
(12) Patent Application Publication
(10) Pub. No.: US 2008/0061363 A1
(43) Pub. Date: Mar. 13, 2008

(54) Integrated transistor device and corresponding manufacturing method

(76) Inventor: Rolf Weis, Dresden (DE)

Correspondence Address: ESCHWEILER & ASSOCIATES LLC, NATIONAL CITY BANK BUILDING, CLEVELAND, OH, 44114, US

(21) Appl. No.: 11/517,639

(22) Filed: Sep. 8, 2006

(51) Int. Cl. H01L 29/94

(52) U.S. Cl. 257/330

(57) ABSTRACT

The present invention provides an integrated transistor device comprising: a semiconductor substrate; a pillar formed in said semiconductor substrate; a gate trench surrounding said pillar; a first source/drain region formed in an upper region of said pillar; a gate dielectric formed on the bottom of said gate trench and surrounding a lower region of said pillar; a gate formed on said gate dielectric in said gate trench and surrounding a lower region of said pillar; and at least one second source/drain region formed in an upper region of said semiconductor substrate adjoining said gate trench. The present invention also provides a corresponding manufacturing method.

### BACKGROUND OF THE INVENTION

1. Field of the Invention

The present invention relates to an integrated transistor device and a corresponding manufacturing method.

2. Description of the Related Art

Junction leakage of an integrated MOSFET transistor to the substrate is one of the key problems in device development. In DRAM applications, for example, these parameters have to be optimized for one contact only, i.e. an asymmetric device. All of these devices for DRAM applications need a body contact.

Recently, asymmetric planar devices, asymmetric three-dimensional devices, such as FINCUT or EUD or double gate devices have been proposed for DRAM applications. However, they all have a non-gated direct path from the node junction to the substrate.

However, still no satisfactory solution that is easy implementable has been found.

### BRIEF SUMMARY OF THE INVENTION

According to a first aspect of the invention as claimed in claim 1, an integrated transistor device comprises: a semiconductor substrate; a pillar formed in said semiconductor substrate; a gate trench surrounding said pillar; a first source/drain region formed in an upper region of said pillar; a gate dielectric formed on the bottom of said gate trench and surrounding a lower region of said pillar; a gate formed on said gate dielectric in said gate trench and surrounding a lower region of said pillar; and at least one second source/drain region formed in an upper region of said semiconductor substrate adjoining said gate trench.

According to a second aspect of the invention as claimed in claim 10, a manufacturing method for an integrated transistor device comprises the steps of: forming a first and second insulation trench in a semiconductor substrate using a mask stripe of a first material having a thickness of x and filling said first and second insulation trench with an insulating material to a level corresponding to an upper surface of said mask strip; forming a mask of said first material having a thickness of 2x, said mask having a window which partly exposes said first and second insulation trench and said mask strip; forming another mask stripe of said first material having a thickness of x in said window having dimensions corresponding to a window scaled down from said window; etching said mask strip, mask and another mask stripe by a thickness of x for exposing said substrate in a first and second window arranged in said window and separated by a part of said mask strip; forming said gate trench surrounding said pillar by at least one etch step using said said mask strip, mask and another mask strip; forming said first source/drain region; forming said gate dielectric; forming said gate; and forming said at least one second source/drain region.

The basic idea underlying this invention is the formation of a device with a fully surrounded gate around the contact on one source/drain side and a conventional contact on the other source/drain side. The source/drain side fully surrounded by the gate has no junction area towards the body which leads to a remarkable reduction of leakage current. The GIDL (GIDL=gate induced strain leakage) can be reduced by vertical arranged potential reduction area, i.e. a lowly doped area <10¹⁸ cm⁻³ between the highly doped source/drain side and the gate.

Preferred embodiments are listed in the respective dependent claims.

According to an embodiment, a first and second insulation trench filled with a dielectric are formed at opposing sides of said pillar, said gate trench and gate extending into said first and second insulation trench.

According to another embodiment, a conductive layer is formed on each of said first and second source/drain regions and extending to a same level of height as said first and second insulation trench, said gate trench being filled with an insulating layer extending to said level of height.

According to another embodiment, a gate contact is formed on and routed through said insulating layer.

According to another embodiment, a first and second source/drain contact are formed on said conductive layer.

According to another embodiment, a channel is formed in the semiconductor substrate below the gate dielectric which has a curved upper surface in a direction perpendicular to a current flow direction.

According to another embodiment, said pillar has curved sidewalls.

According to another embodiment, a channel is formed in the semiconductor substrate below the gate dielectric which includes upper corners covered by said gate dielectric and gate.

According to another embodiment, another second source/drain region is formed in an upper region of said semiconductor substrate adjoining said gate trench at a location opposite to said at least one second source/drain region.

### DESCRIPTION OF THE DRAWINGS

In the Figures:

FIG. 1a)-f) to 10a)-f) show schematic layouts of a manufacturing method for an integrated semiconductor structure according to a first embodiment of the present invention;

FIG. 11a)-f) to 13a)-f) show schematic layouts of a manufacturing method for an integrated semiconductor structure according to a second embodiment of the present invention;

FIG. 14a)-f) to 16a)-f) show schematic layouts of a manufacturing method for an integrated semiconductor structure according to a third embodiment of the present invention; and

FIG. 17a)-f) and 18a)-f) show schematic layouts of a manufacturing method for an integrated semiconductor structure according to a fourth embodiment of the present invention.

In the Figures, identical reference signs denote equivalent or functionally equivalent components.

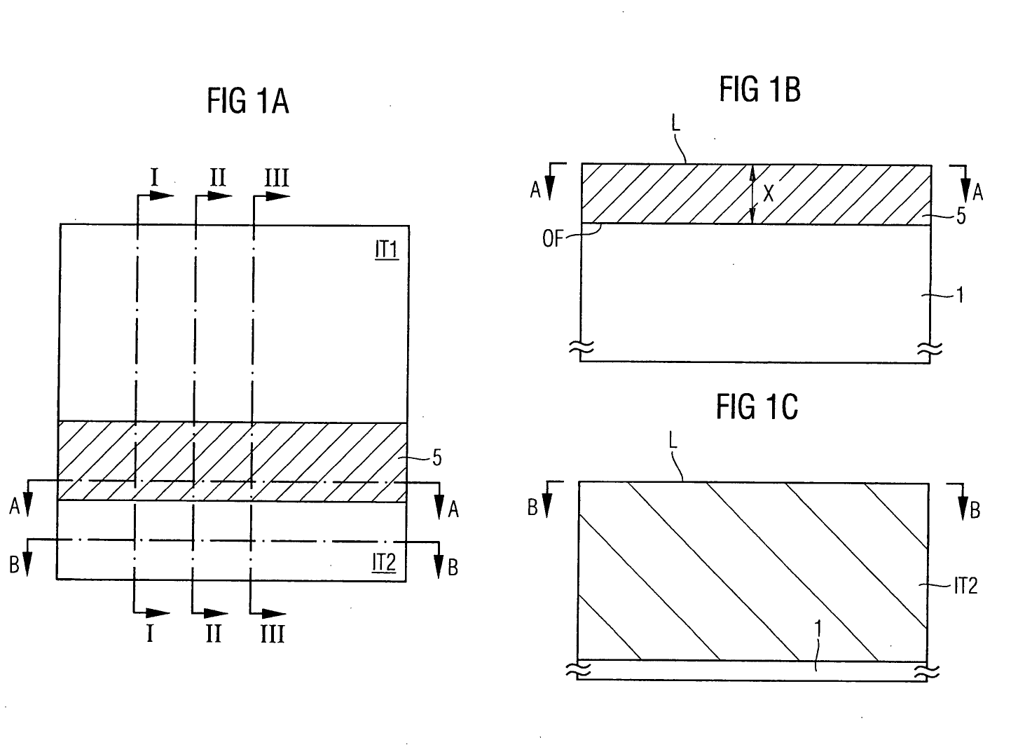

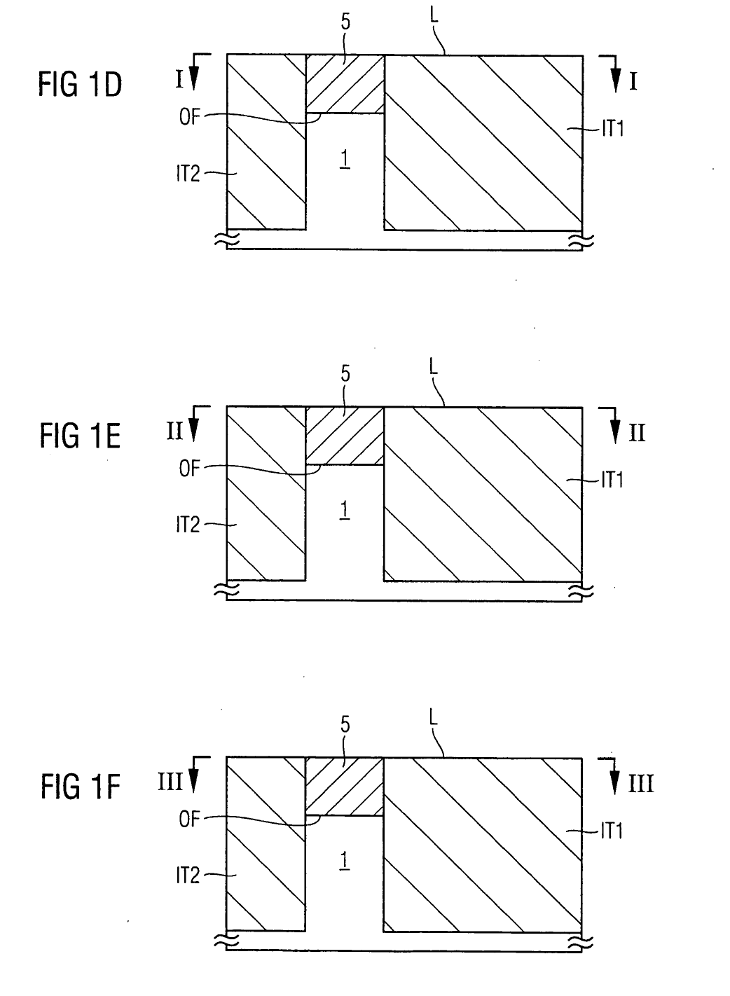

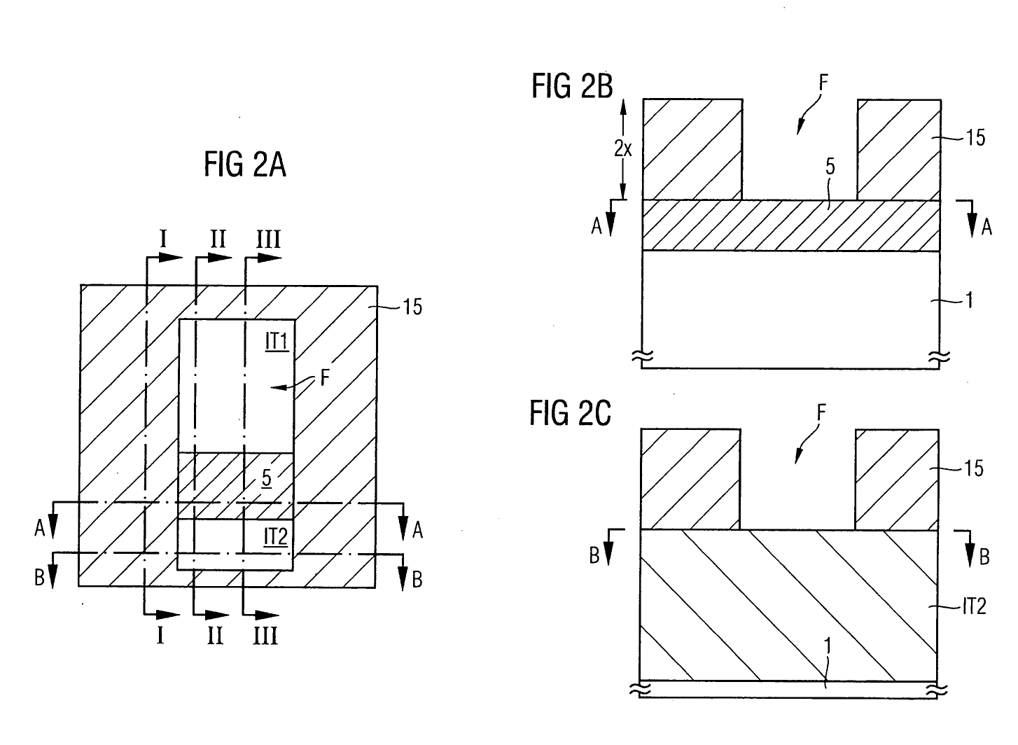

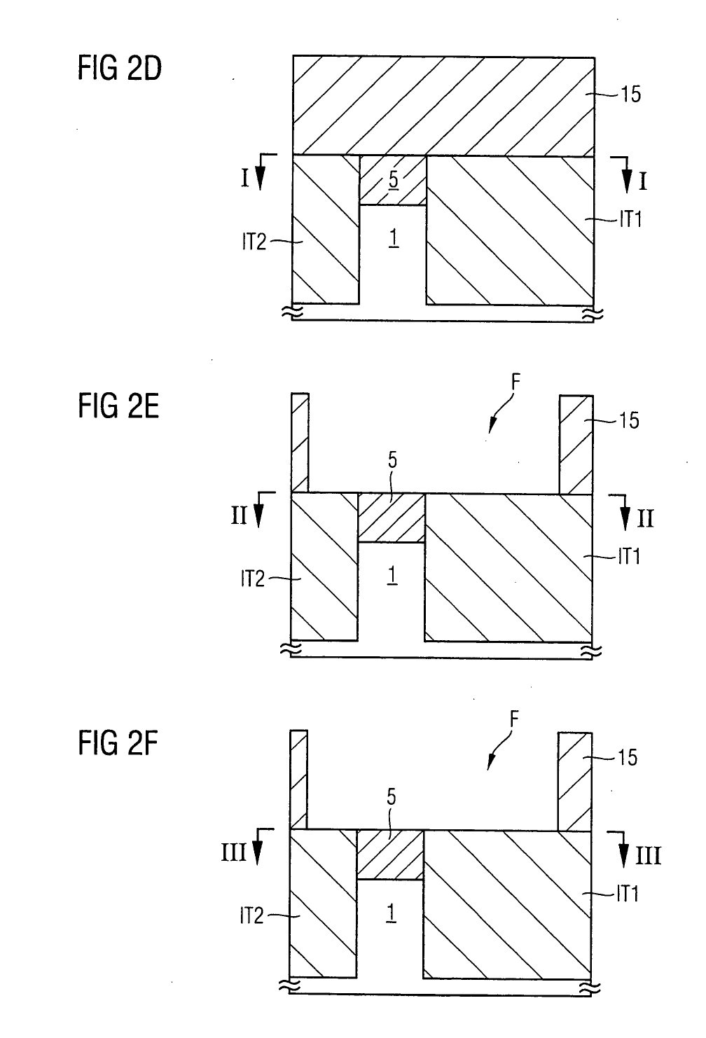

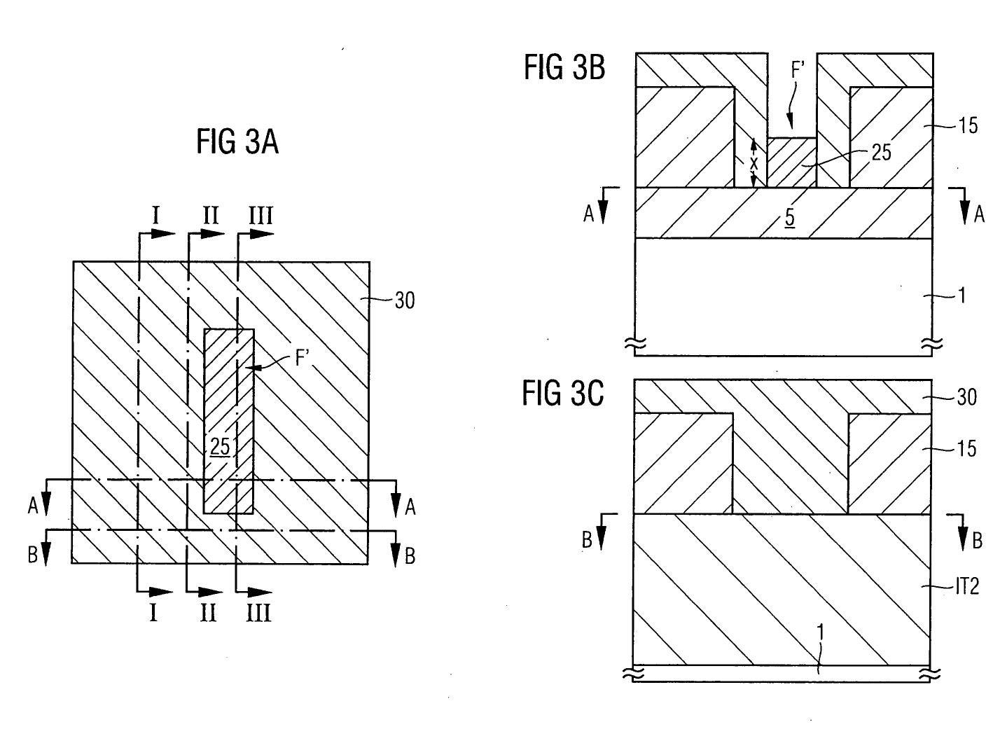

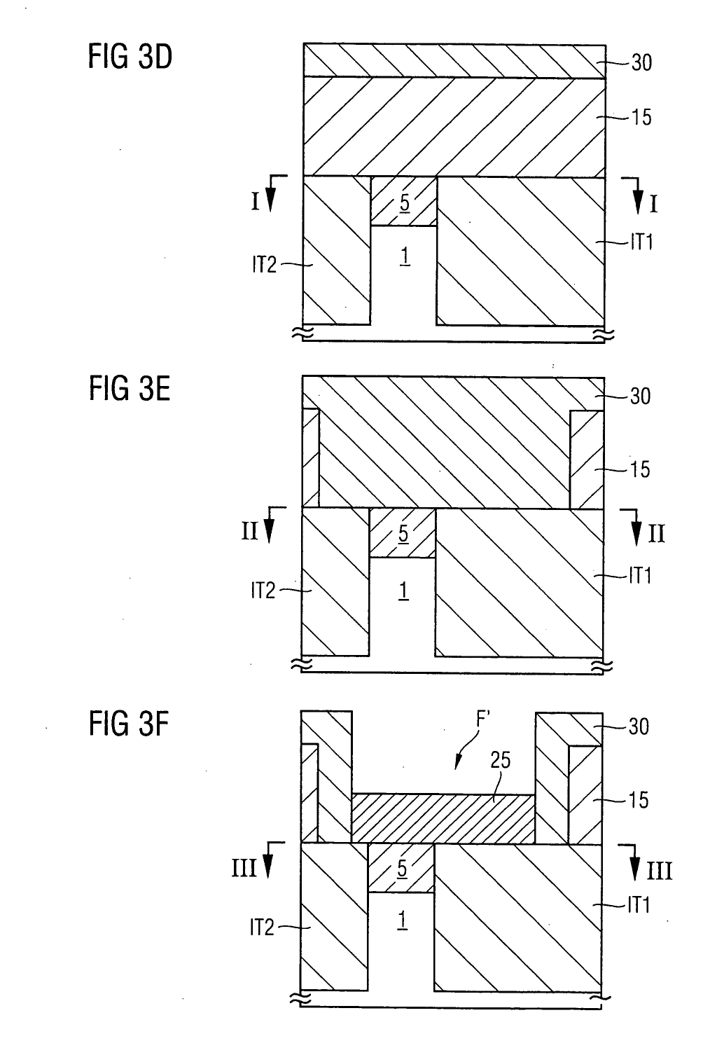

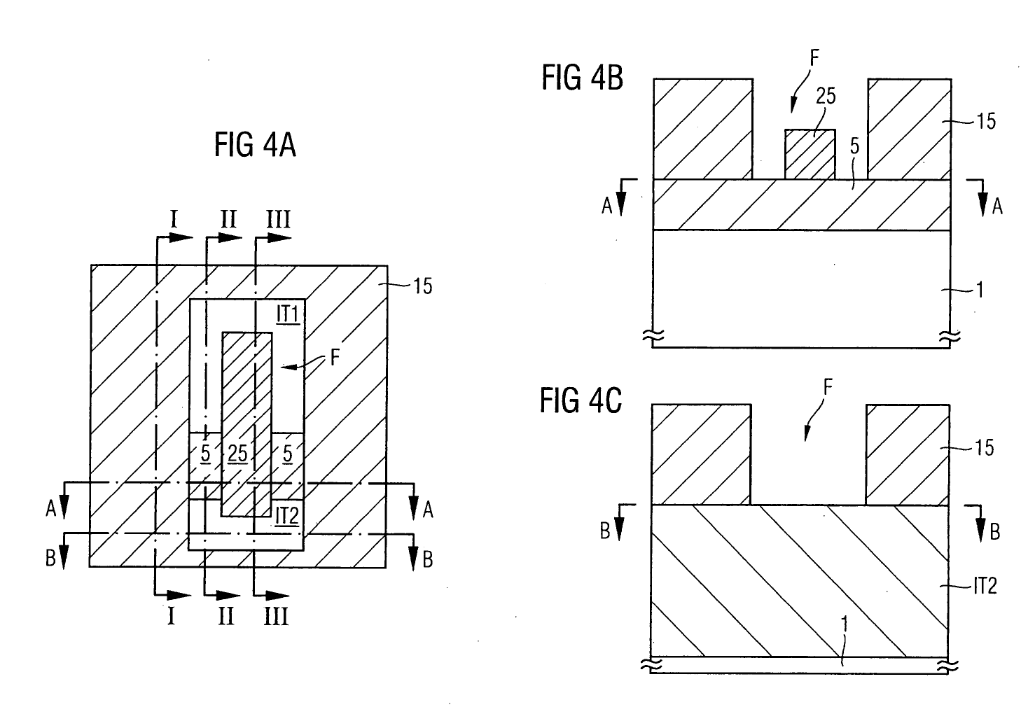

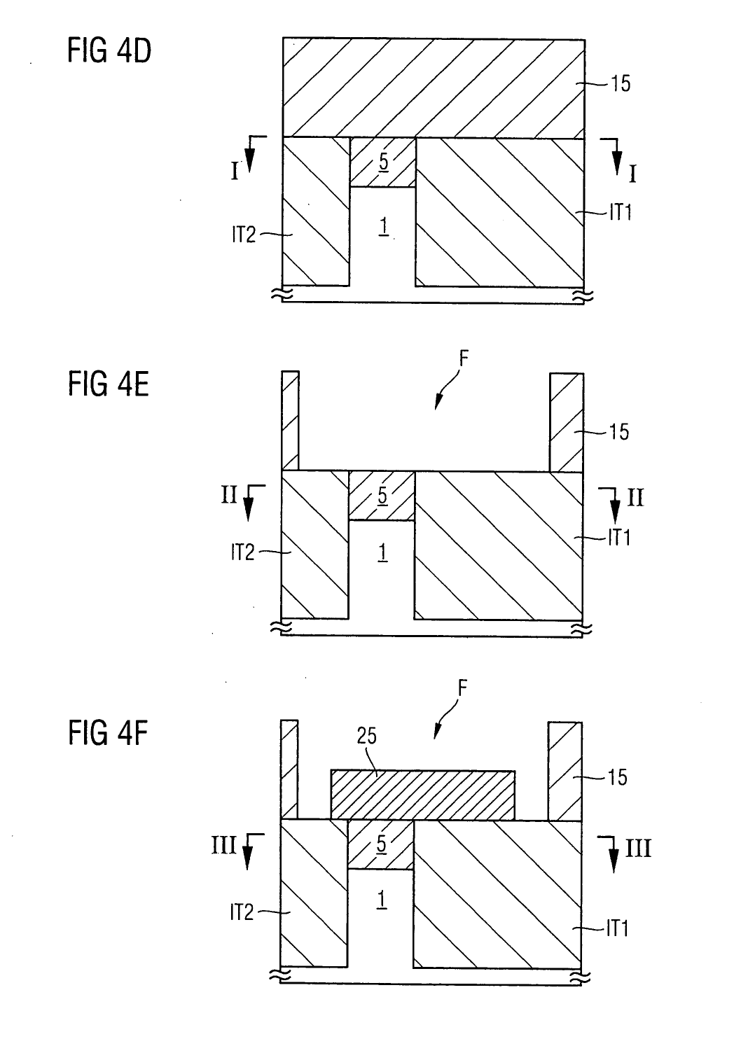

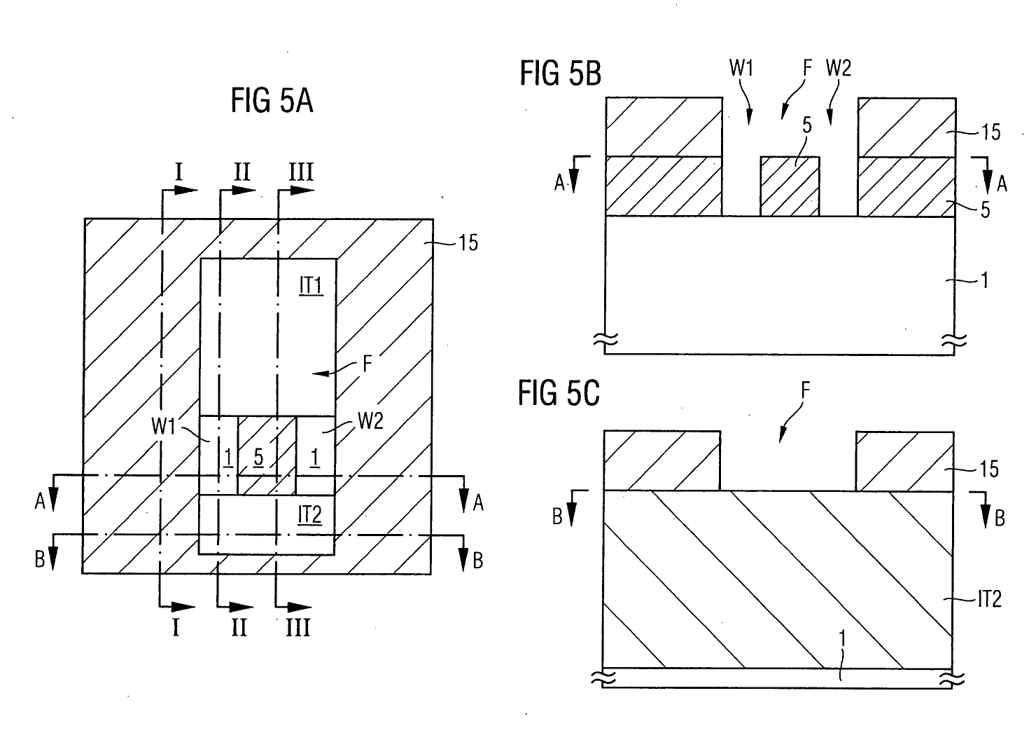

In each of FIG. 1 to 18, a) denotes a plain view, b) denotes a cross section along line A-A of the plain view of a), c) denotes a cross section along line BB of the plain view of a), d) denotes a cross section along line I-I of the plain view of a), e) denotes a cross section along line II-II of the plain view of a), and f) denotes a cross section along line III-III of the plain view of a).

### DESCRIPTION OF THE PREFERRED EMBODIMENTS

FIG. 1a)-f) to 10a)-f) show schematic layouts of a manufacturing method for an integrated semiconductor structure according to a first embodiment of the present invention.

FIG. 1a)-f) show a silicon semiconductor substrate 1 in which insulation trenches IT1 and IT2 filled with a dielectric insulating material such as silicon dioxide have been formed. The formation of said insulating trenches IT1, IT2 has been carried out by means of a silicon nitride mask stripe 5, provided on an upper surface OF of said substrate 1. After an etch step for forming the insulation trenches IT1, IT2, the insulating filling material has been deposited and treated by a chemical mechanical polishing step wherein the silicon nitride mask stripe 5 has been used as a polish stop. Therefore, the upper surface of the silicon nitride mask stripe 5 and the insulation trenches IT1, IT2 are on a same level L of height. It should be mentioned that the thickness of the silicon nitride mask stripe 5 amounts to x where x is in the order of several 25-200 nm.

Although not shown here, it is clear that insulation trenches could also be provided at the remaining two sides of the layout of FIG. 1a).

In a subsequent process step shown in FIG. 2a)-f), a hard mask 15 is formed on the structure of FIG. 1a)-f) having a thickness of 2x, i.e. double the thickness of the silicon nitride mask stripe 5 lying thereunder. The material of said hard mask 15 is preferably also silicon nitride. The hard mask 15 includes a window F which exposes a part of said silicon nitride mask stripe 5 and of said insulation trenches IT1, IT2. It should be mentioned that during the step of forming said hard mask window F, the underlying oxide of said insulation trenches IT1, IT2 can be used for endpoint detection.

In a next process step which is depicted in FIG. 3a)-f), a silicon oxide liner layer 30 is deposited on the structure of FIG. 2a)-f) and subjected to an oxide liner spacer etch step for opening said oxide liner layer 30 only on the bottom of said window F such that a smaller window F′ is formed. Thereafter, another silicon nitride layer 25 is deposited and etched back in said smaller window F′ to a final thickness of x, i.e. the thickness of said silicon nitride mask stripe 5 or half of the thickness of said hard mask 15.

Thereafter, as shown in FIG. 4a)-f) the silicon oxide liner layer 30 is stripped in an etch step, said etch step being stopped on the upper surface of said hard mask 15. As may be obtained from FIG. 4a), the process state of FIG. 4a)-f) differs from the process status of FIG. 2a)-f) by the additional silicon nitride stripe 25 having the extensions of said smaller window F′.

In a next process step, a transfer etch is performed which means that the exposed silicon nitride layers 5, 15, 25 are reduced by thickness of x which results in the process state shown in FIG. 5a)-f). This transfer etch step etches silicon nitride selective to silicon oxide and to silicon. Thus, two windows W1, W2 exposing said substrate 1 are formed between said insulation trenches IT1, IT2, said windows W1, W2 being separated by a part of said silicon nitride mask stripe 5.

As may be obtained from FIG. 6a)-f), a combined silicon oxide/silicon etch step is now performed for forming a gate trench GW having. The gate trench has one depth in the substrate 1 and in the neighboring insulation trenches IT1, IT2. Therefore, the etching must proceed much faster in silicon oxide.

Alternatively, a silicon oxide etch step may be performed first, and thereafter a silicon oxide/silicon etch step having no selectivity.

The etch process for said gate trench GW forms a pillar 1a in said substrate 1 which is completely surrounded by said gate trench GW, as may be particularly obtained from FIG. 6f). In the substrate 1 below the bottom of the gate trench GW, there is the channel of the transistor device to be formed.

After said etching process of said gate trench GW, optionally channel implants into said windows W1, W2 may be performed for adjusting the characteristics of the transistor channel CH.

Having regard to FIG. 7a-f), a gate dielectric layer 40, for example made of silicon oxide, is formed on the exposed silicon substrate 1 in said gate trench GW, f.e. by thermal oxidation or by high-k material deposition or a combination thereof. Thereafter, a polysilicon layer 50 is deposited and recessed in said gate trench GW which polysilicon layer 50 forms the gate of the transistor device to be formed. It should be mentioned that the material for the gate is not limited to polysilicon, but also other conductive materials can be used, such as metals.

Thereafter, another silicon oxide layer 60 is deposited over the entire structure and polished back to the upper surface of the remaining hard mask 15 by a chemical mechanical polishing step. This leads to the process state shown in FIG. 7a)-f).

In another process step which is illustrated in FIG. 8a)-f), an silicon oxide/silicon nitride etch step is performed which removes a thickness of x of said silicon oxide layer 60 and the remaining thickness x of said hard mask from the structure of FIG. 7a)-f).

Further, with reference to FIG. 9a)-f), the exposed parts of said silicon nitride mask stripe 5 are stripped by a selective etch step, and thereafter an ion implantation is performed into the exposed surface of the substrate 1 in order to form a first source/drain region S in said pillar 1a and second and third source/drain regions D1, D2 at the surface OF of said substrate 1. Then, a poly-silicon layer 70 is deposited and polished back to the level L of the upper surface of the adjoining insulation trenches IT1, IT2.

Finally, as shown in FIG. 10a)-f), another insulating layer 100, for example made of silicon oxide, is deposited over the entire structure, and thereafter source/drain contacts CD1, CD2, source/drain contact CS and a gate contact CG are formed for contacting said first and second source/drain regions D1, D2, said source/drain region S, and said gate region 50.

As may be seen in FIG. 10e), the channel CH of the device according to this embodiment has a planar upper surface in a direction perpendicular to the current flow direction.

It should be mentioned here that the source/drain contact CD2 as well as the source/drain region D2 are optional and not necessary. In particular, this source/drain region D2 and source/drain contact CD2 are useful, if the transistor according to this embodiment is used symmetrically.

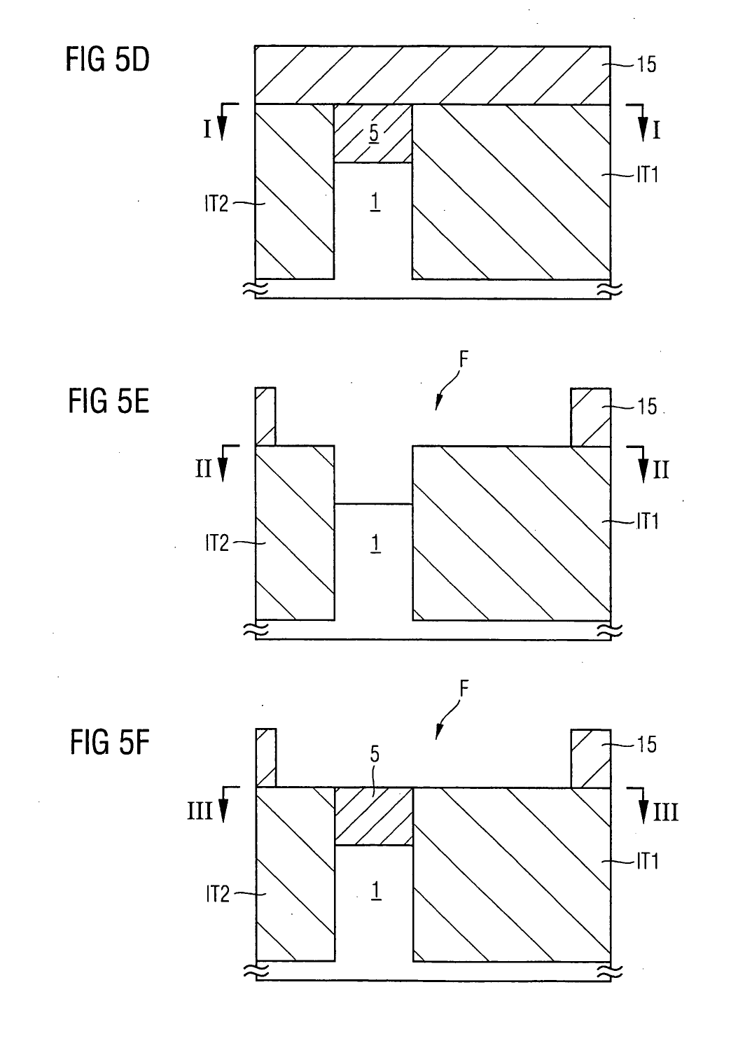

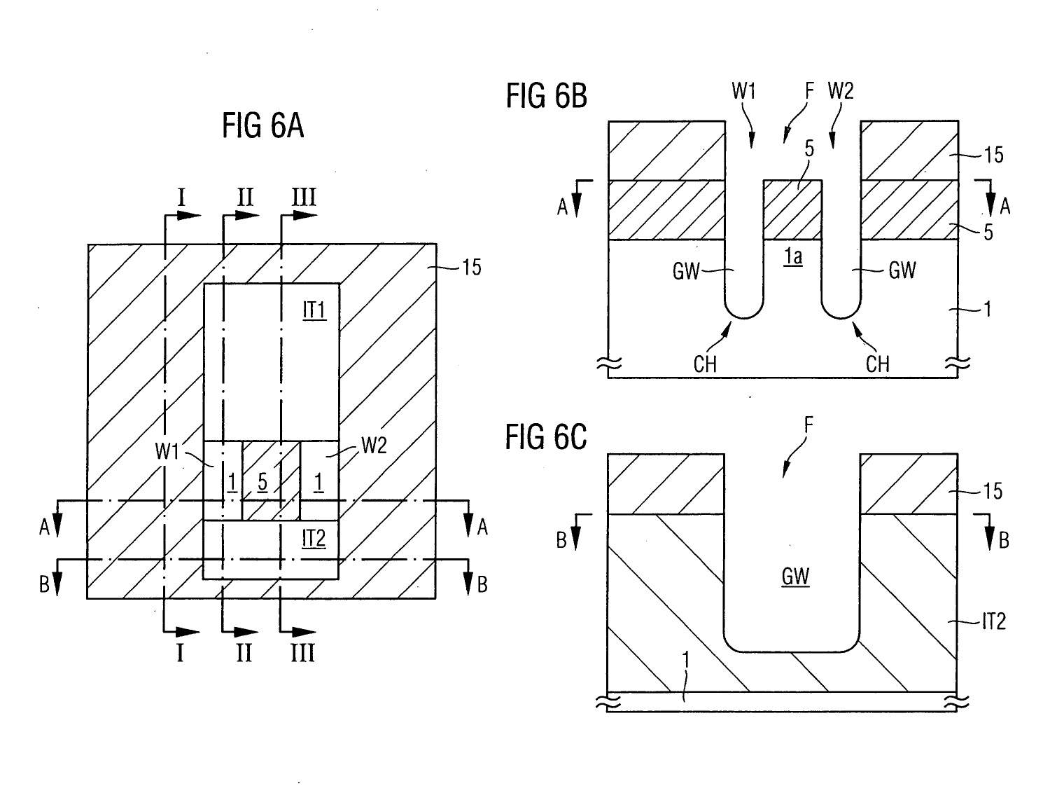

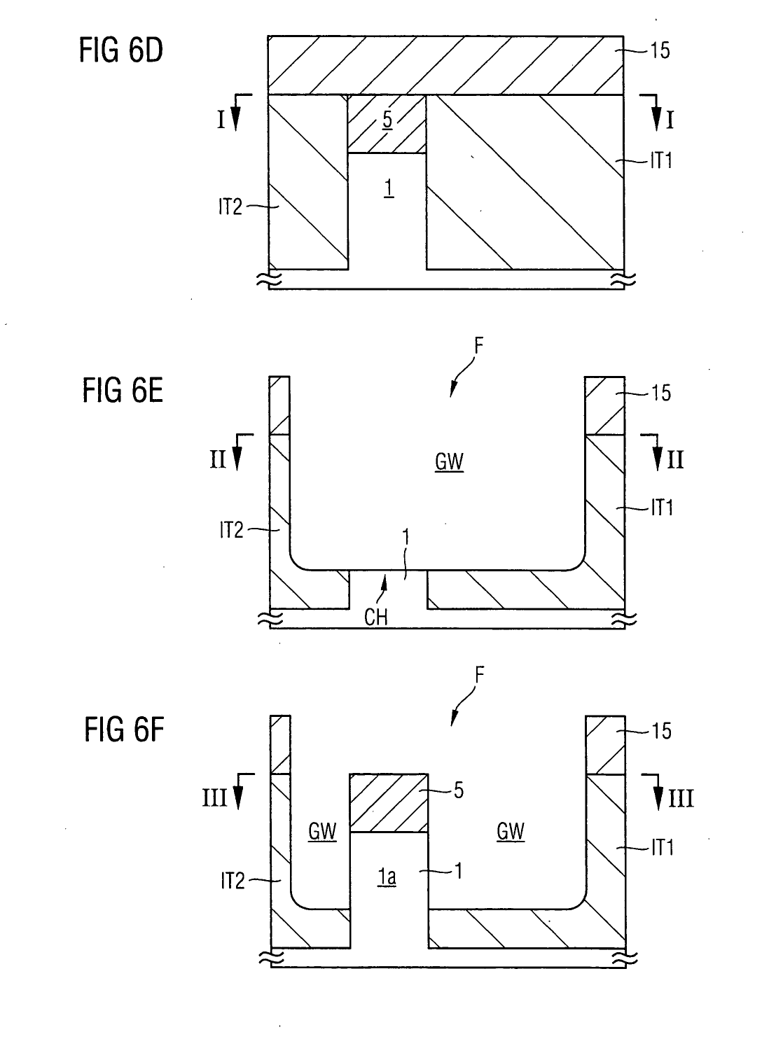

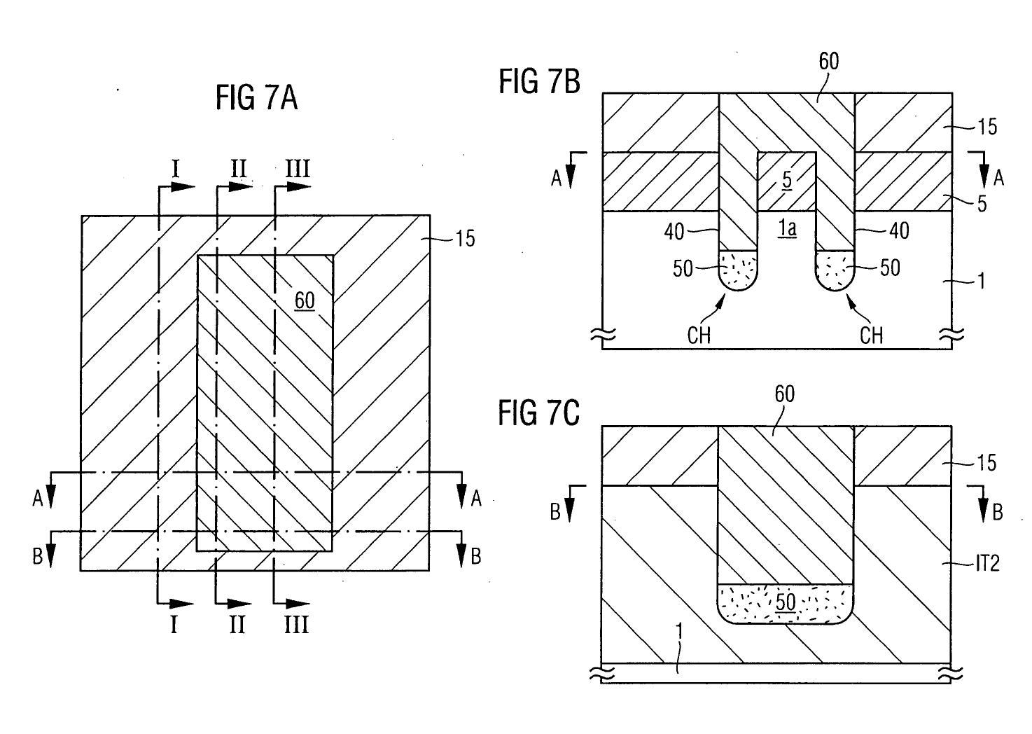

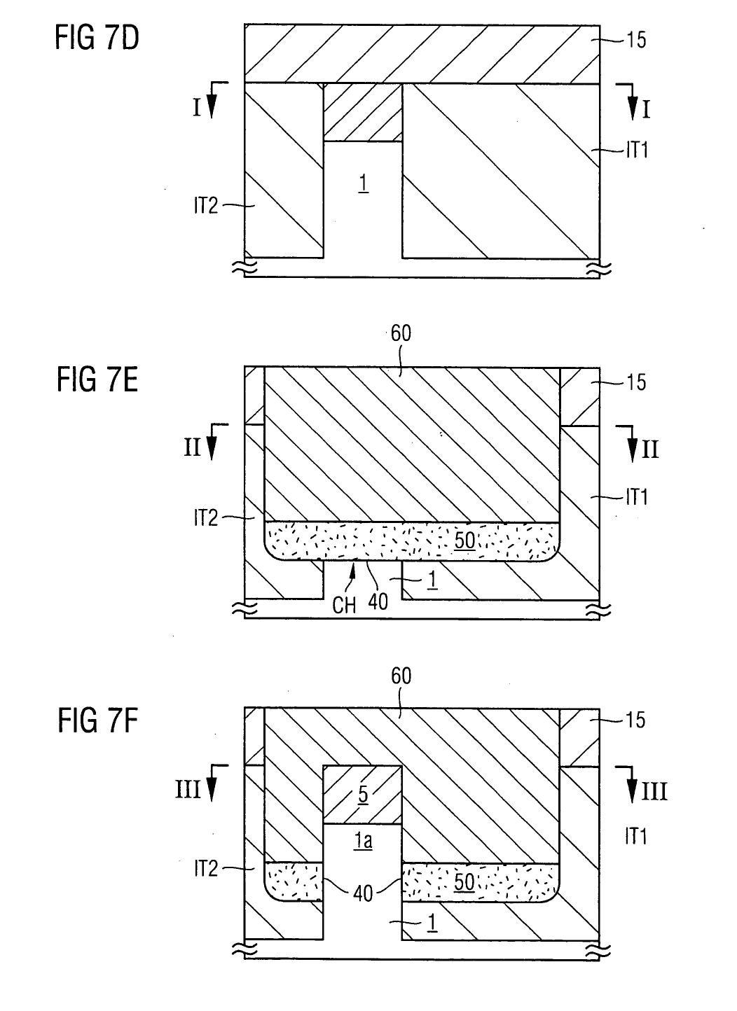

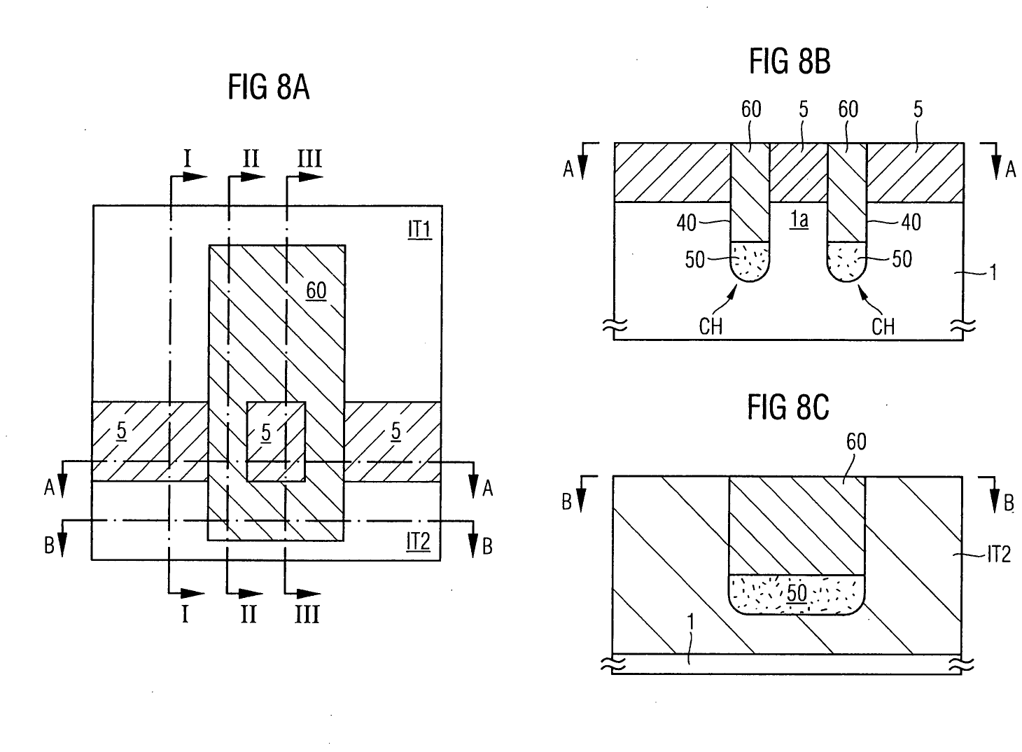

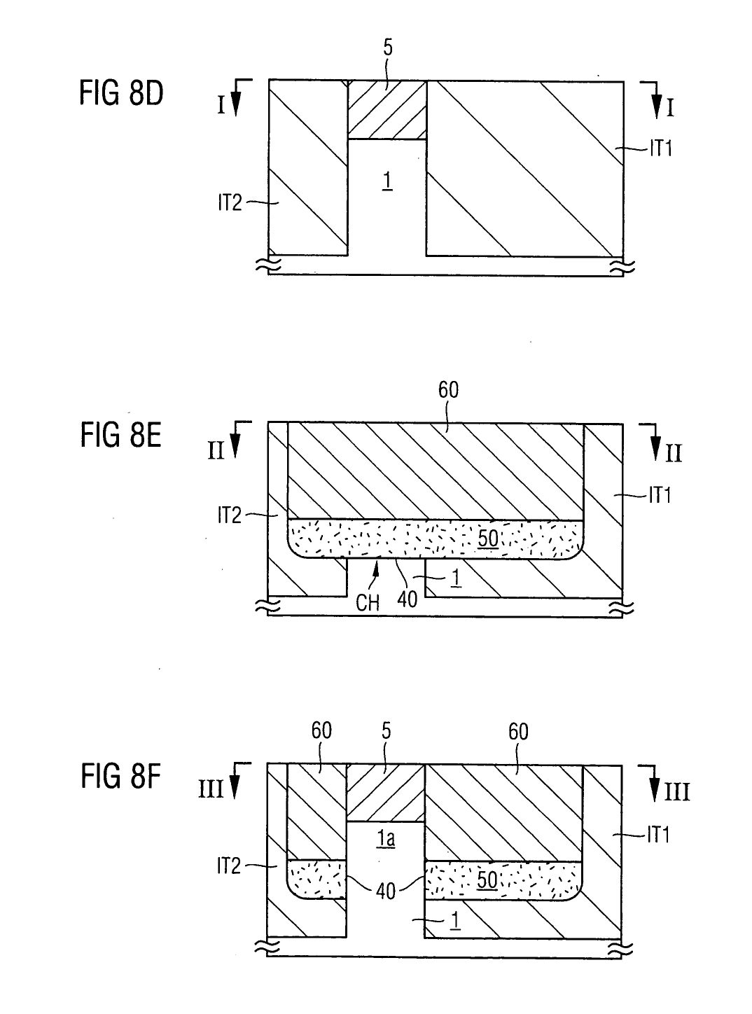

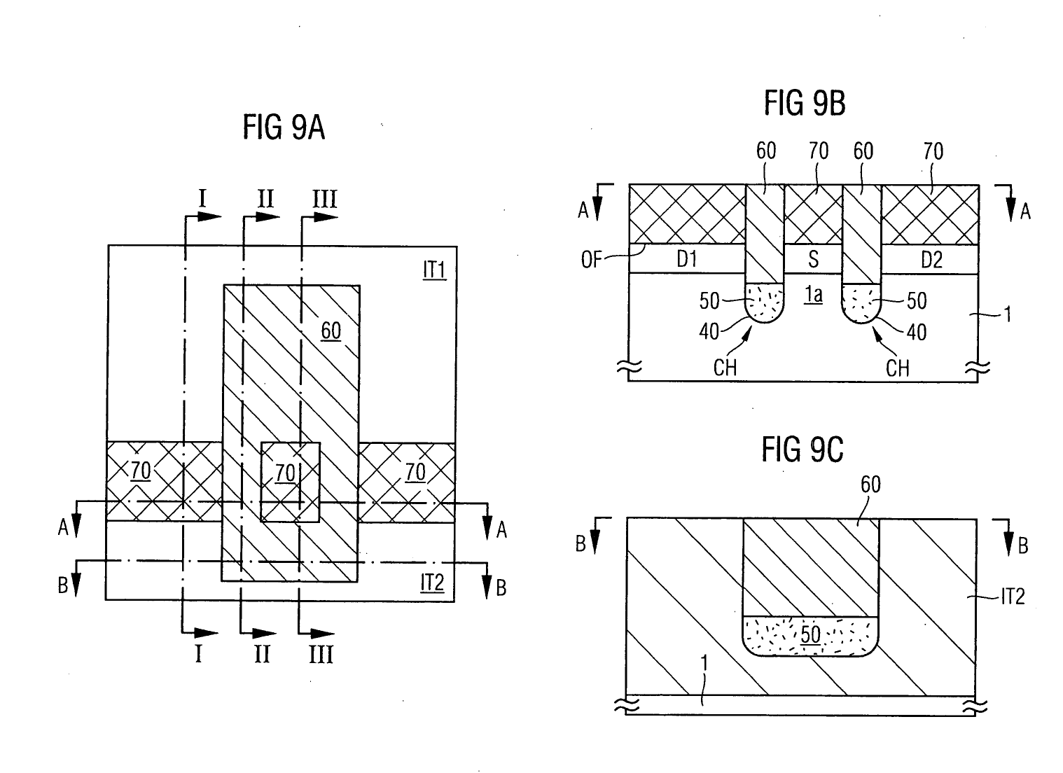

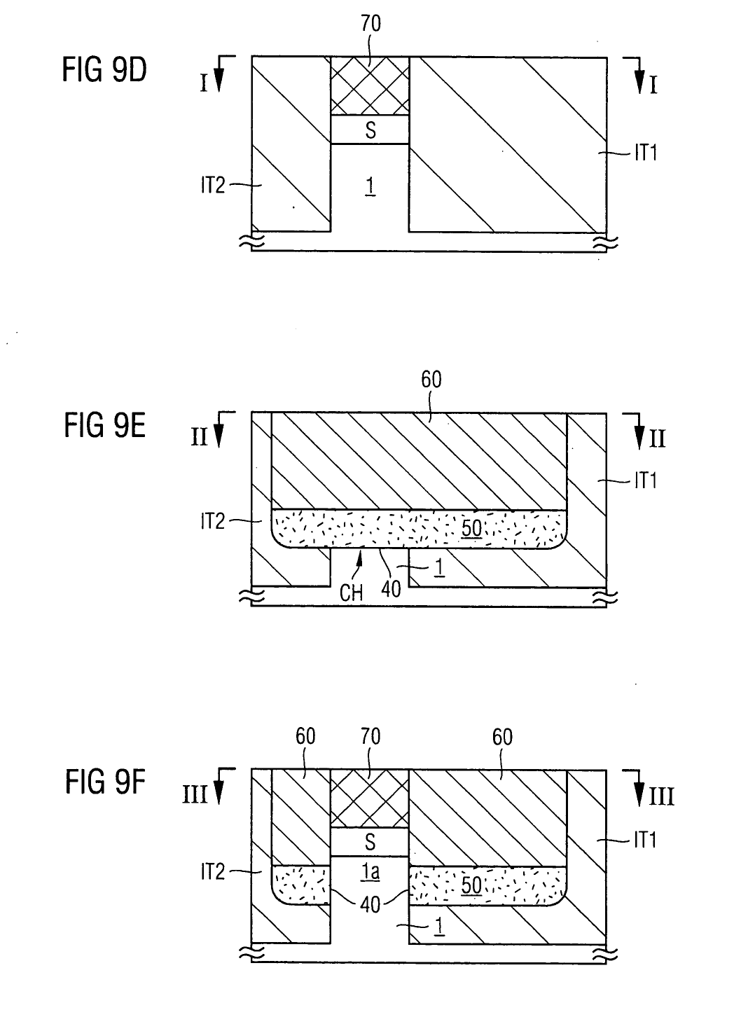

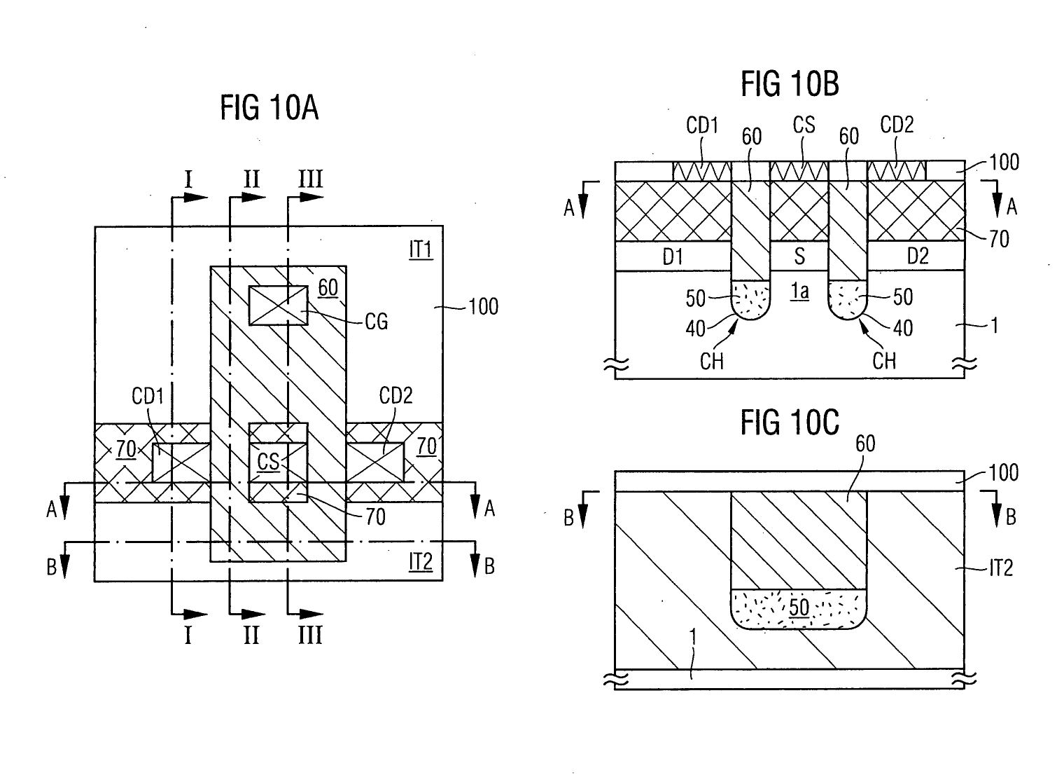

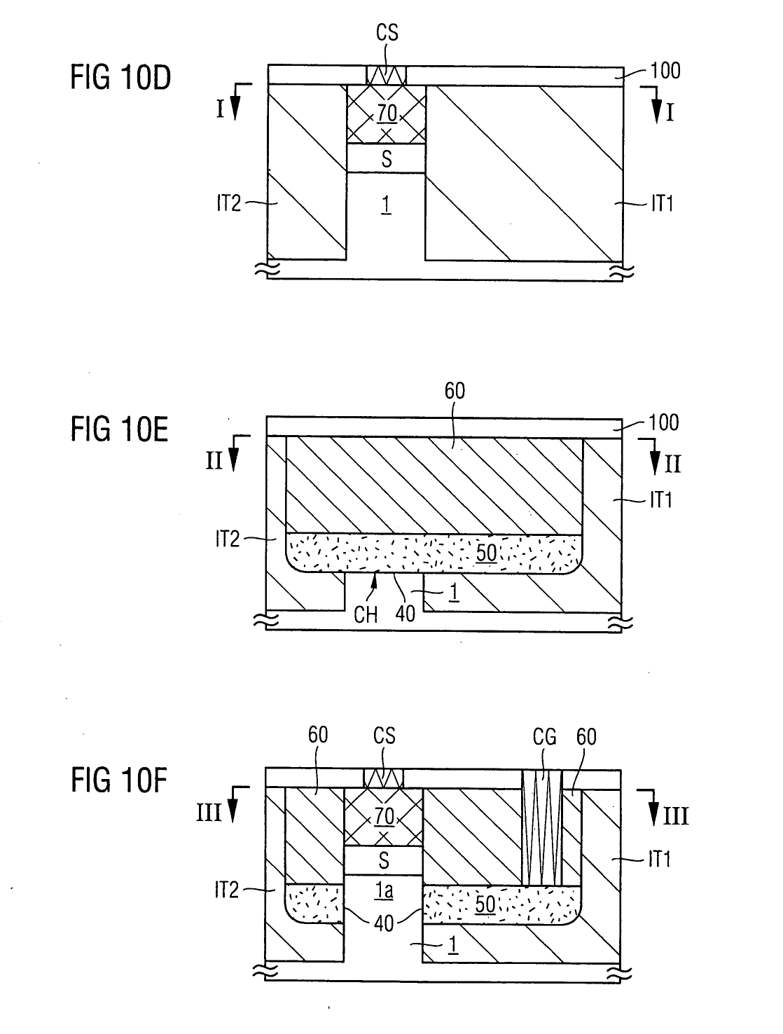

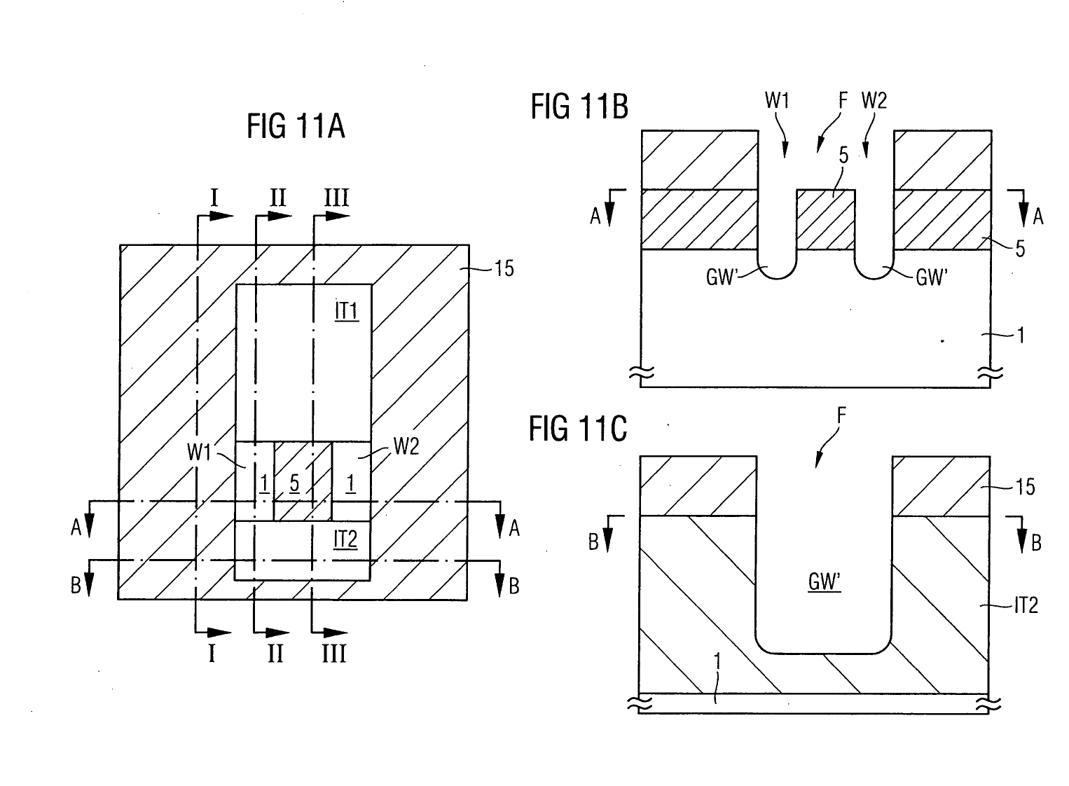

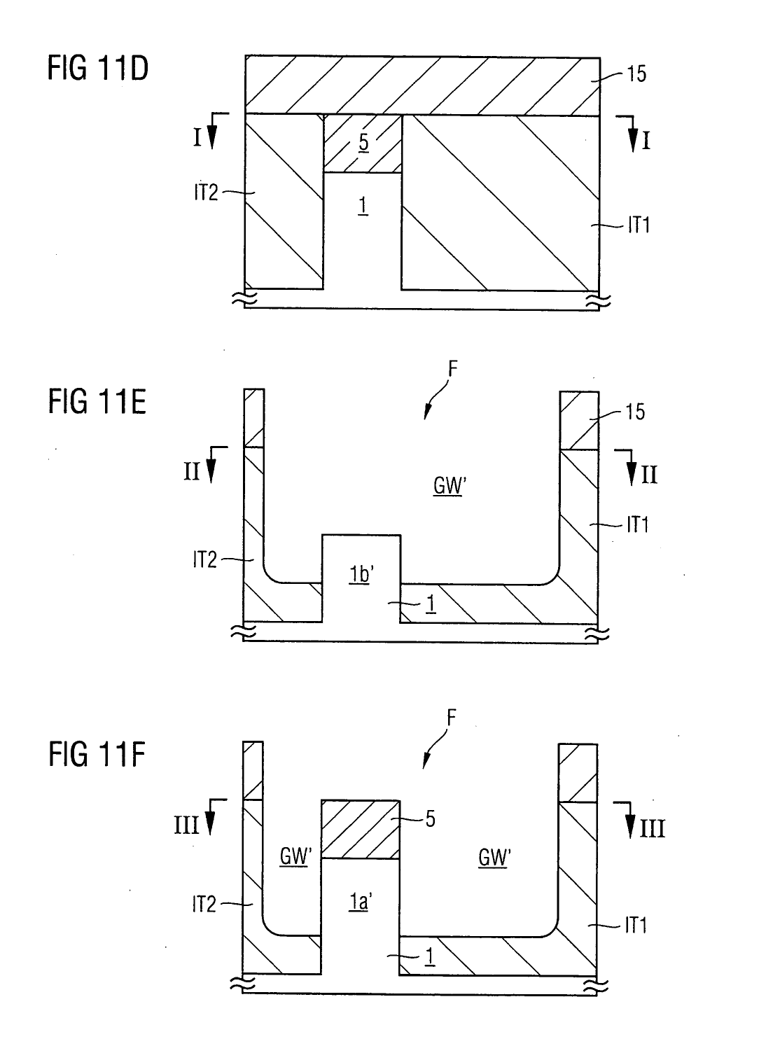

FIG. 11a)-f) to 13a-f show schematic layouts of a manufacturing method for an integrated semiconductor structure according to a second embodiment of the present invention.

The second embodiment starts with the process state shown in FIG. 5a)-5f).

Having regard to FIG. 11a)-f), the etch process for the gate trench GW′ of the second embodiment is started with a silicon oxide/silicon etch step which etches silicon oxide much faster than silicon such that the final depth of the gate trench GW′ in the insulation trenches IT1, IT2 is reached, thereafter whereas the final depth of the gate trench GW′ in the silicon substrate 1 is not yet reached thereafter. Clearly, this etch step is highly selective with respect to the silicon nitride which is used as a mask.

Thereafter, a silicon etch step is performed which is highly selective with respect to silicon oxide and silicon nitride. In this silicon etch step the substrate 1 is etched isotropically which leads to the process state shown in FIG. 12a)-f).

Particularly, this silicon etch step results in a lateral thinning of said pillar 1a′ resulting in curved sidewalls thereof and a curved surface 1b′ of the channel region CH′ below the gate trench GW′, as seen perpendicular to the current flow direction in FIG. 12e). By this silicon thinning step, the electrical characteristics of the transistor to be formed can be varied in a broad way.

The process steps following the process state of FIG. 12a)-f) correspond to the process steps of FIG. 7a)-f) to 10a)-f), and therefore a repeated description thereof will be omitted here. Only the final process state is shown in FIG. 13a)-f) which corresponds to the process state shown in FIG. 10a)-f).

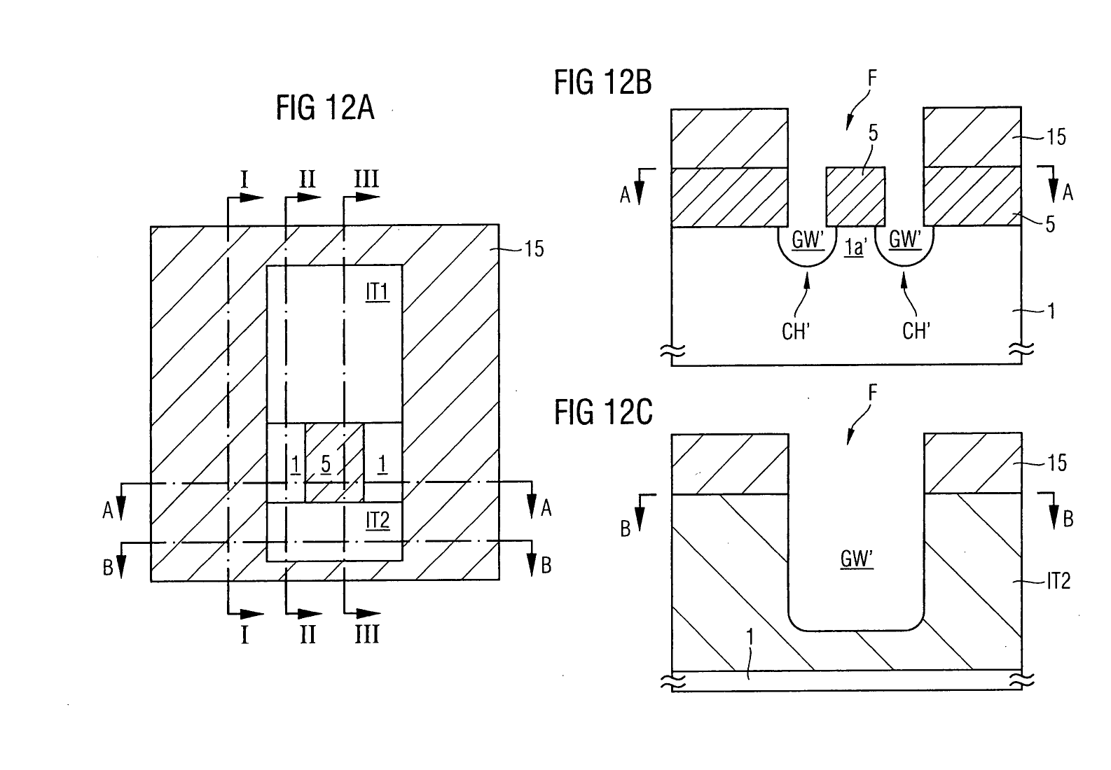

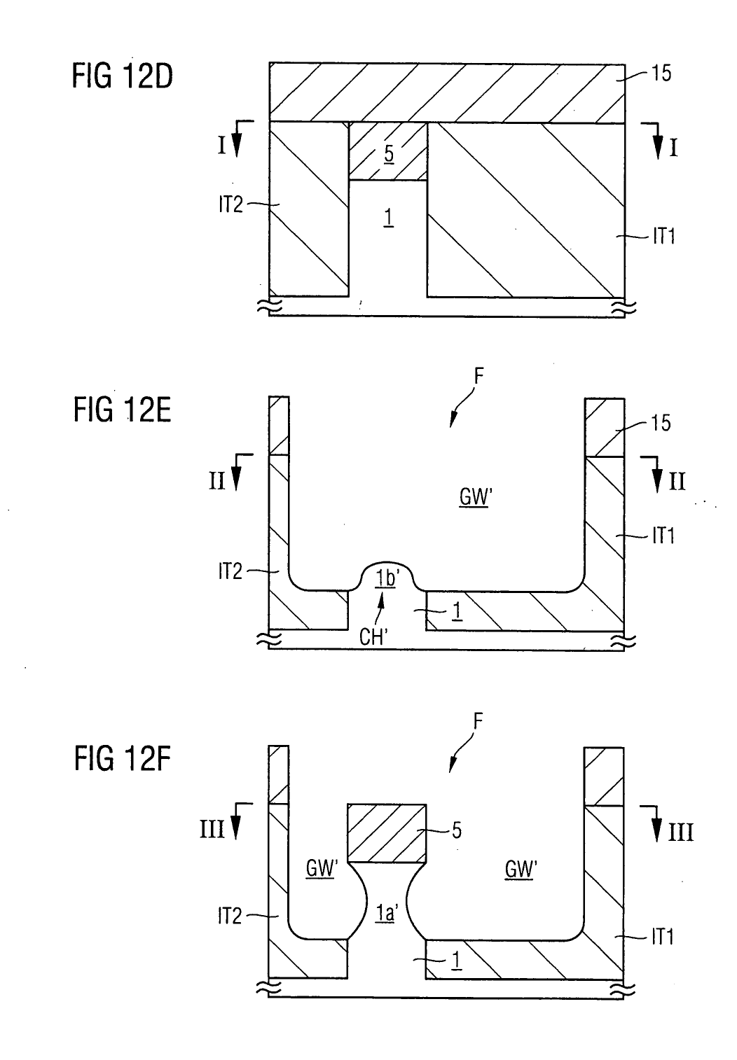

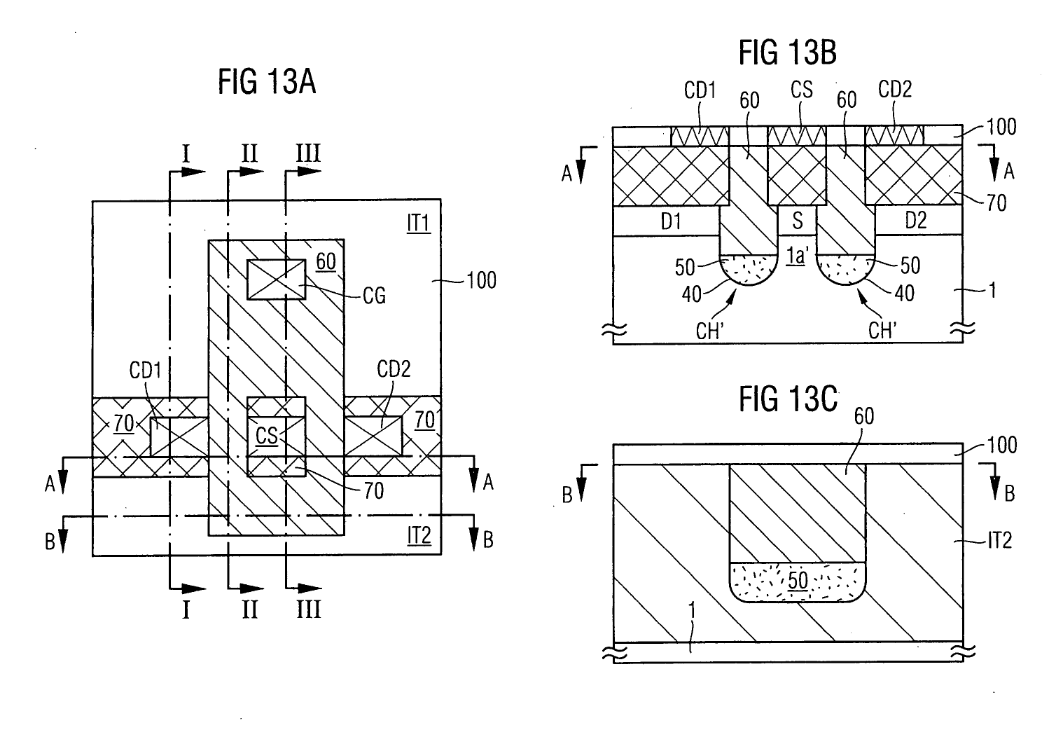

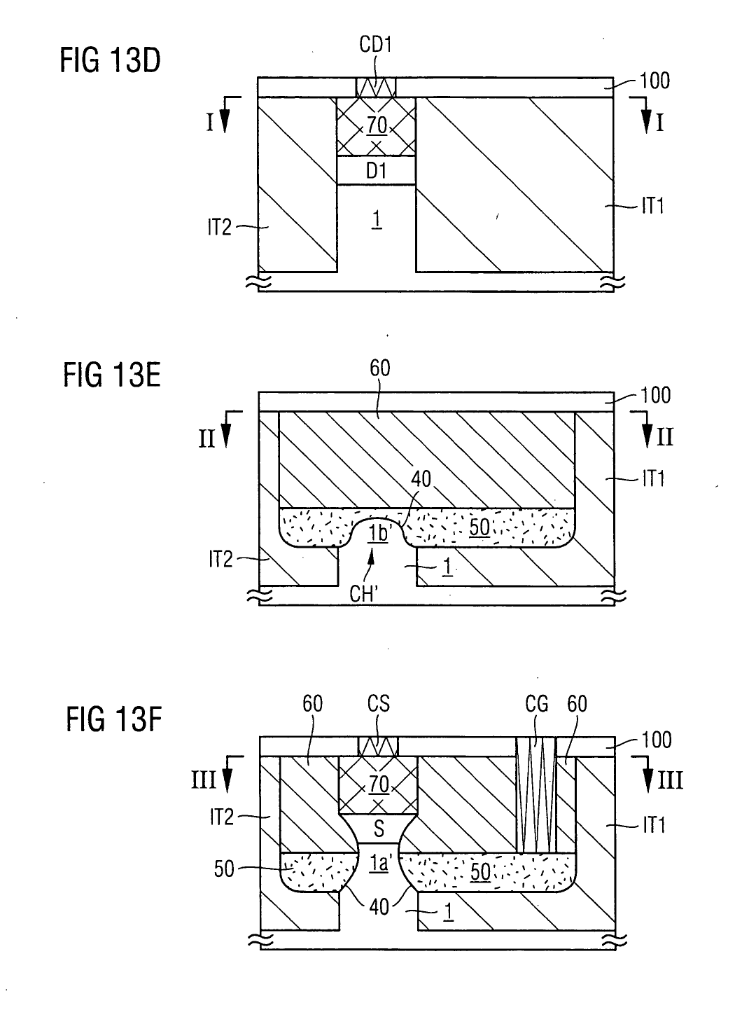

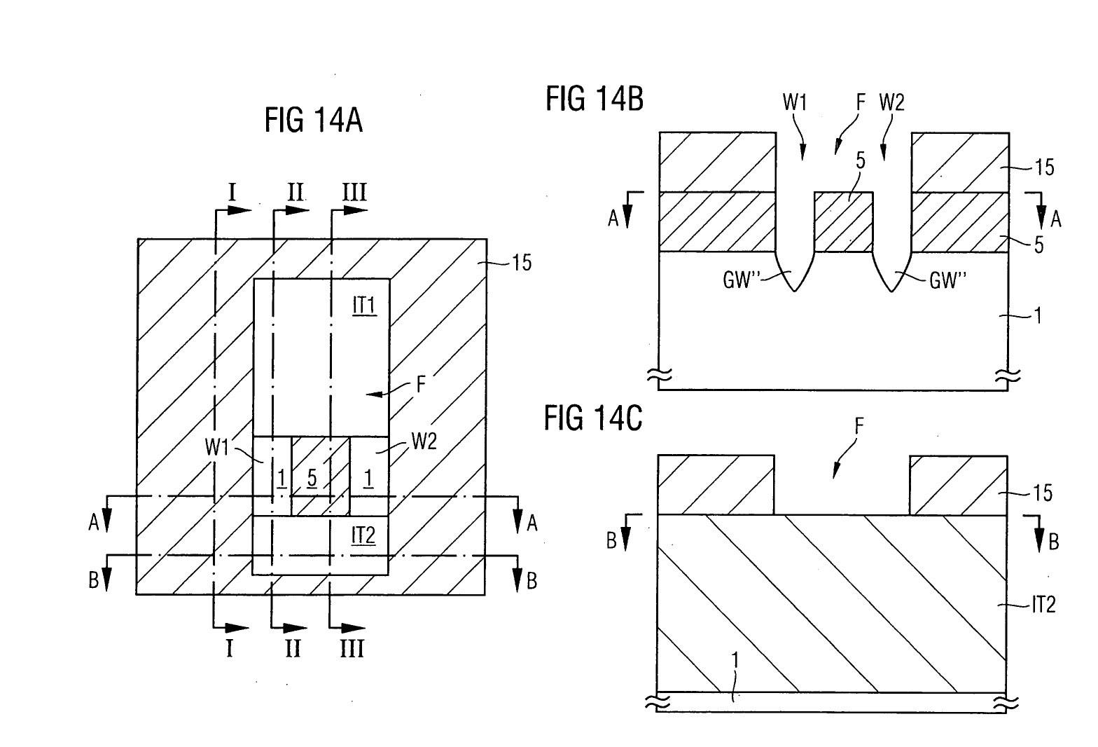

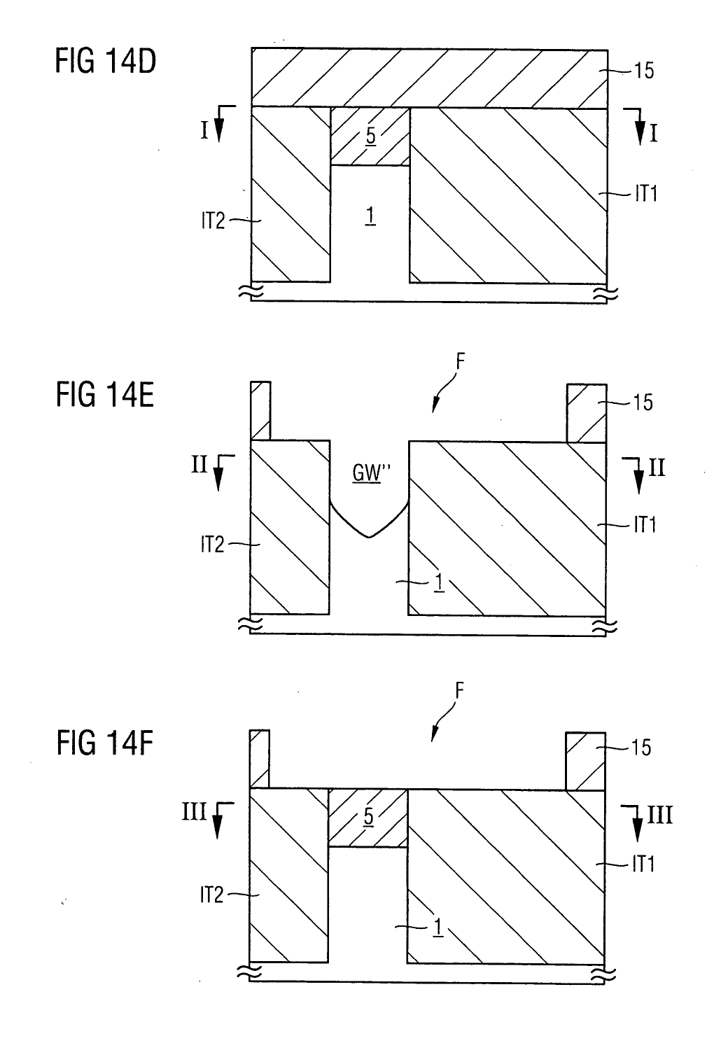

FIG. 14a)-f) to 16a)-f) show schematic layouts of a manufacturing method for an integrated semiconductor structure according to a third embodiment of the present invention.

The third embodiment also starts with the process state shown in FIG. 5a)-f). In this third embodiment, the etch step for forming the gate trench GW″ commences with a silicon etch step which is highly selective over silicon oxide and silicon nitride and forms a tapered gate trench GW″ in the silicon substrate 1 as shown in FIG. 14a)-f).

Thereafter, a silicon oxide silicon etch step is performed which etches the silicon oxide much faster than silicon. This results in the process state shown in FIG. 15a)-f) which reveals that the channel region CH″ under the gate trench GW″ has a curved surface 1c, the curvature of which is opposite to the curvature of the surface 1b′ of the second embodiment, as may be particularly obtained from FIG. 15e).

The process steps following FIG. 15a)-f) correspond to the process steps already explained above with regard to FIG. 7a)-f) to 10a)-f), and a repeated description will be therefore omitted here. Only shown in FIG. 16a)-f) is the final process state corresponding to the process state shown in FIG. 10a)-f).

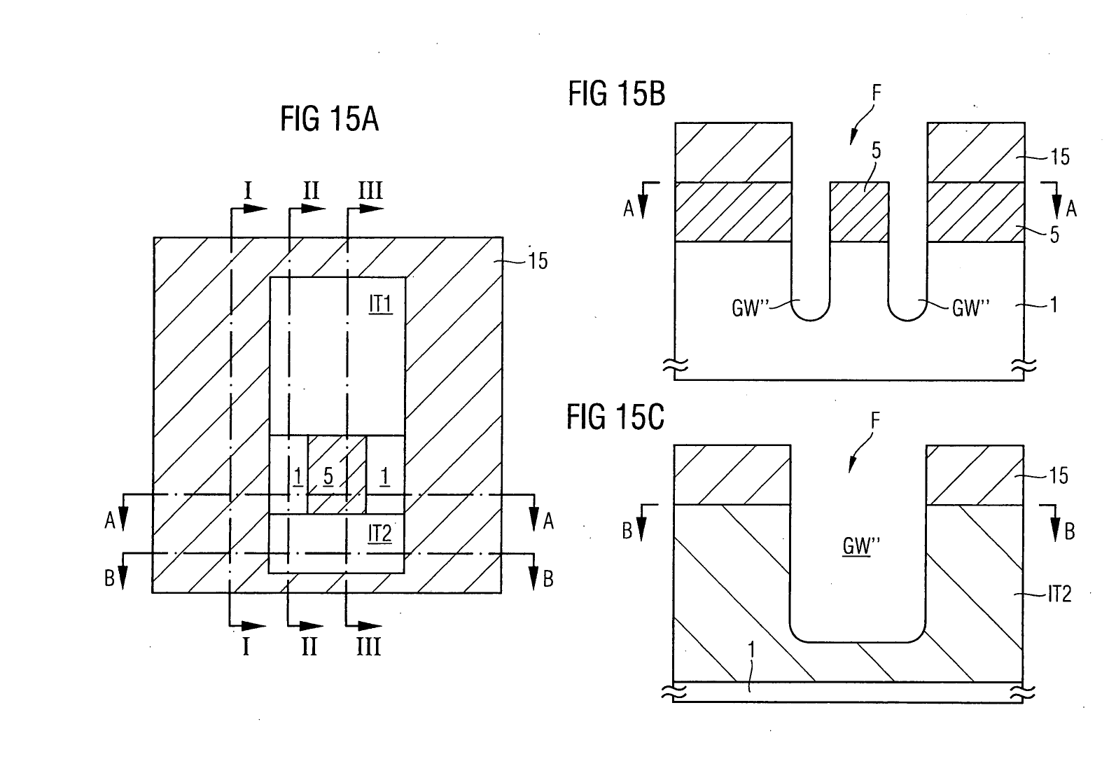

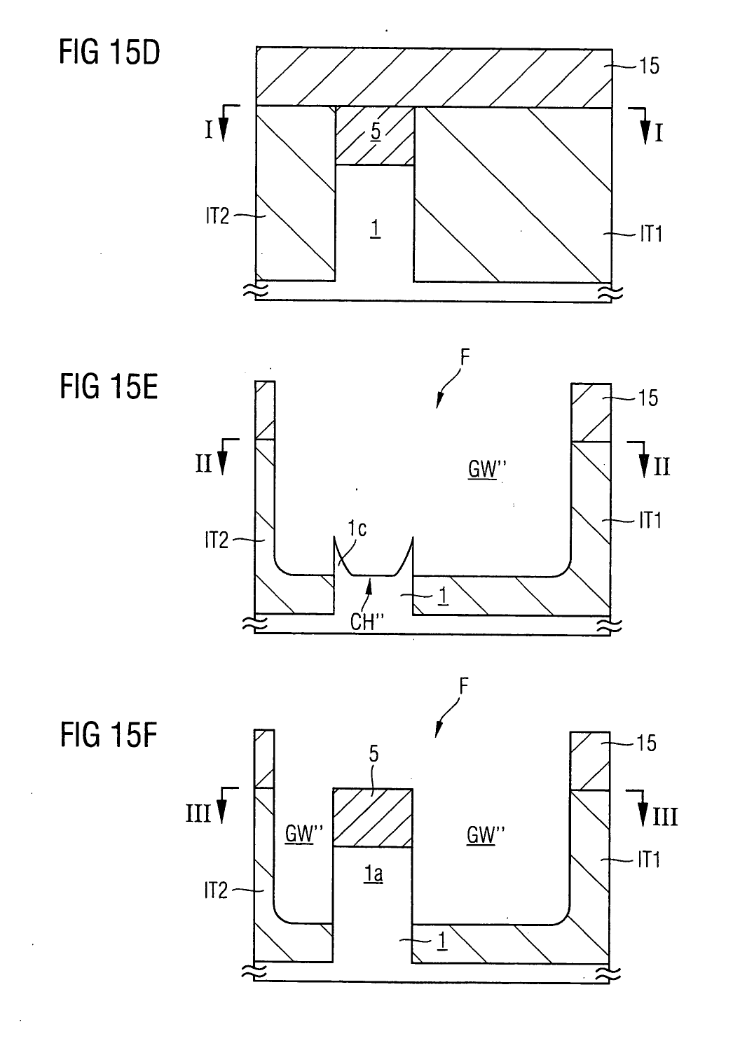

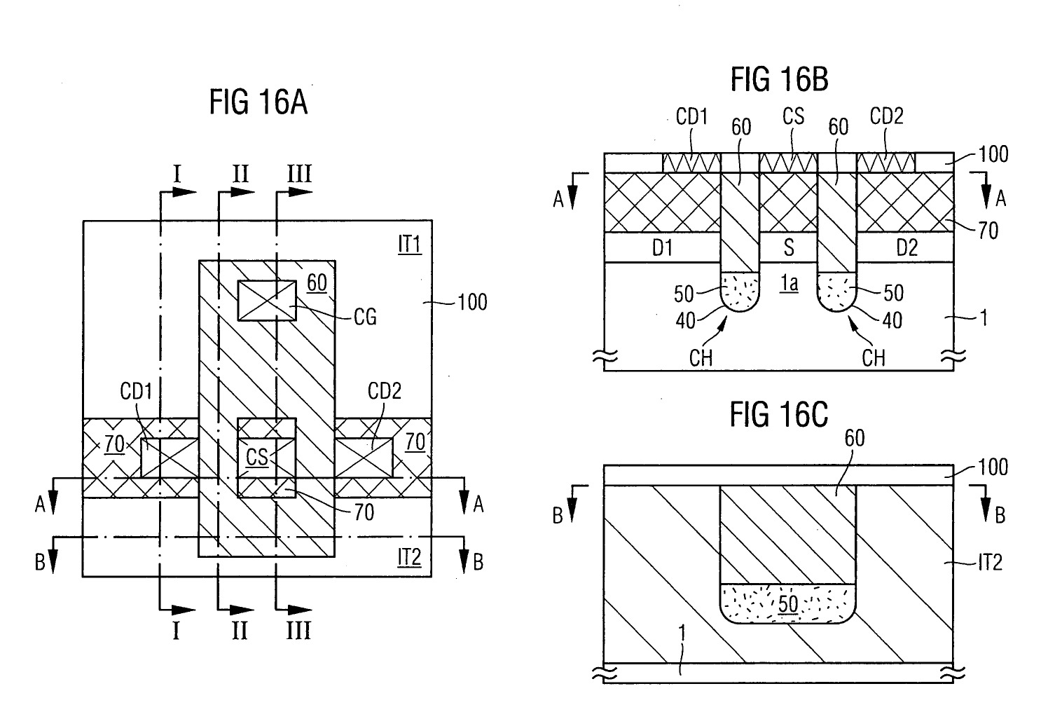

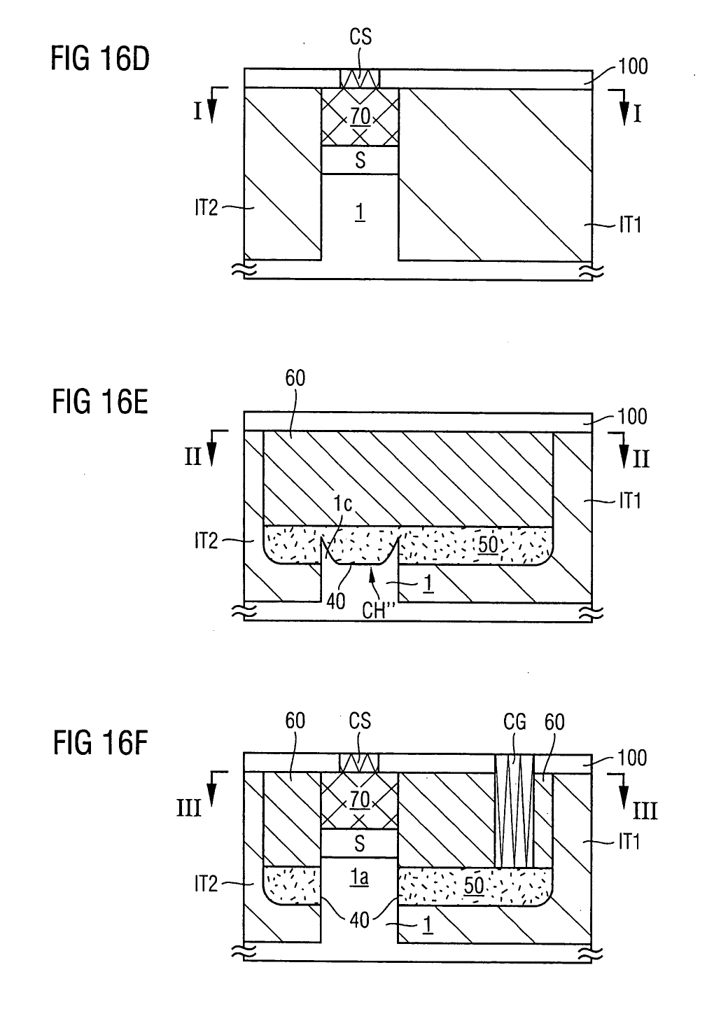

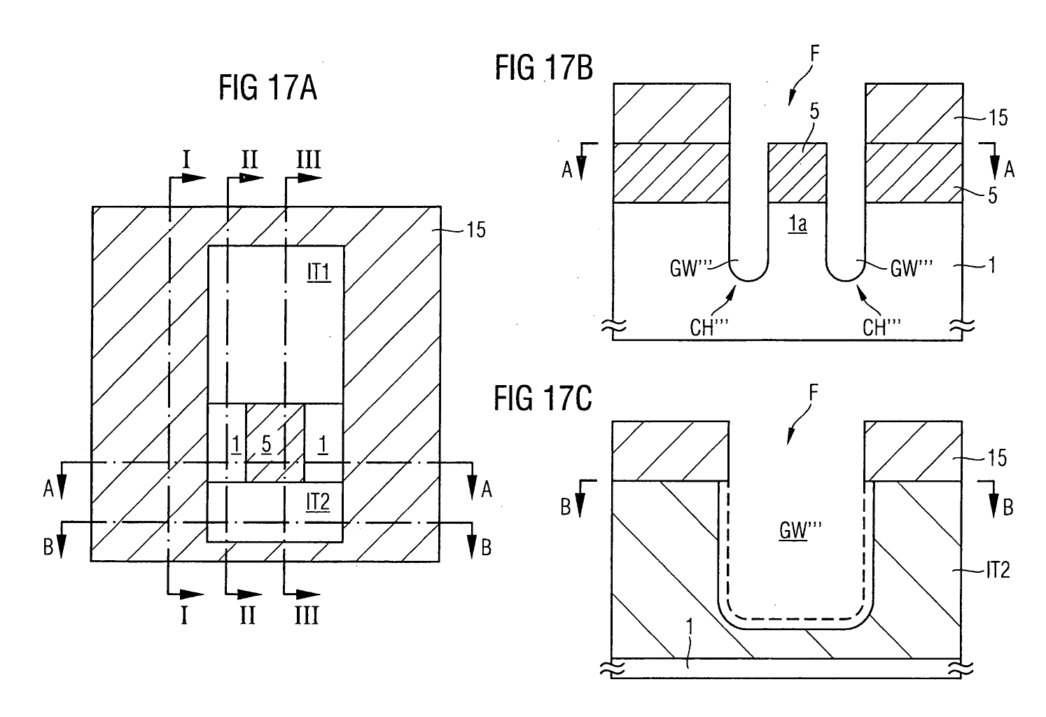

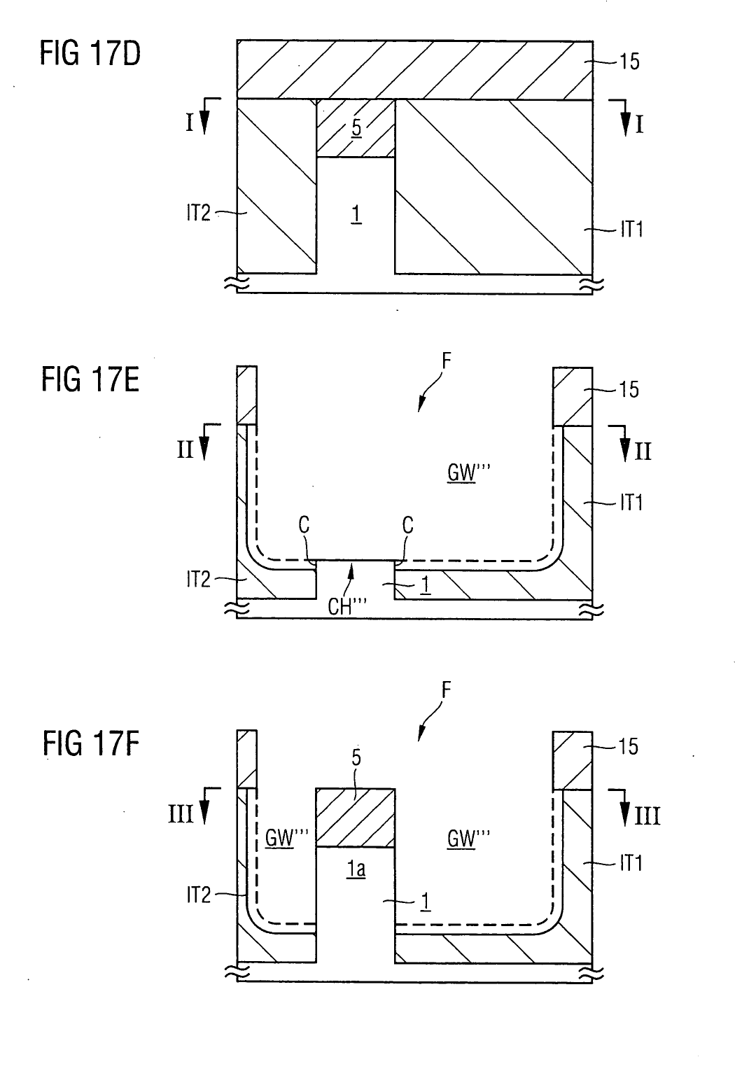

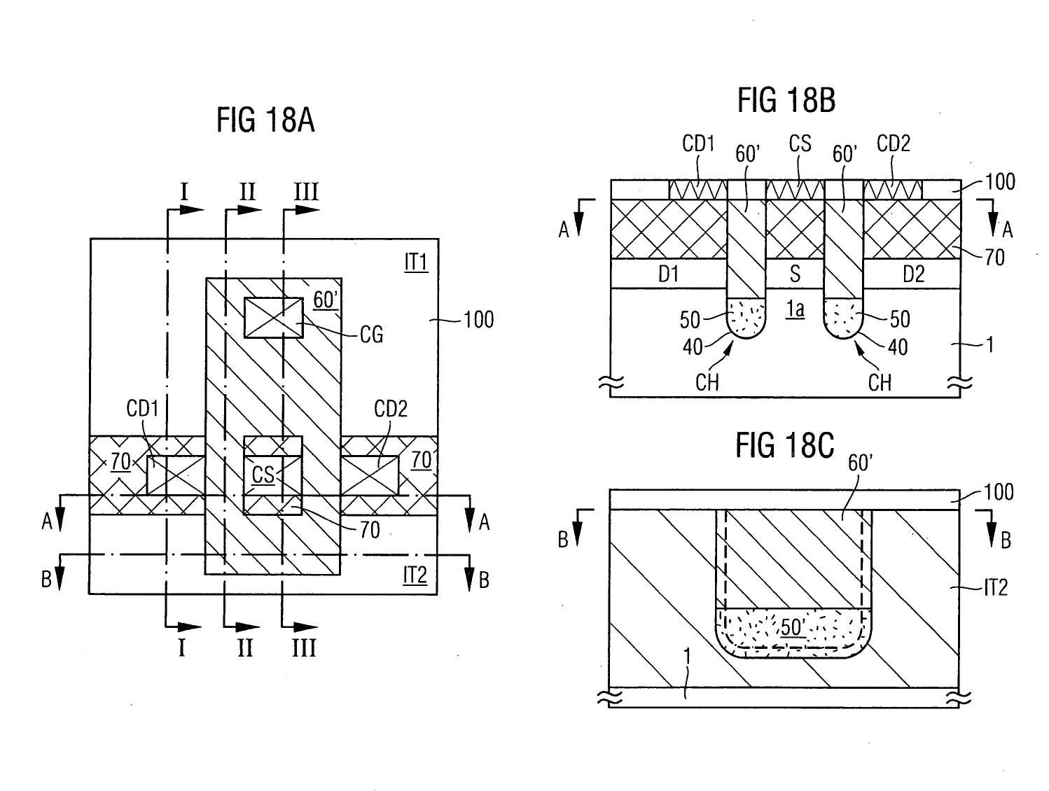

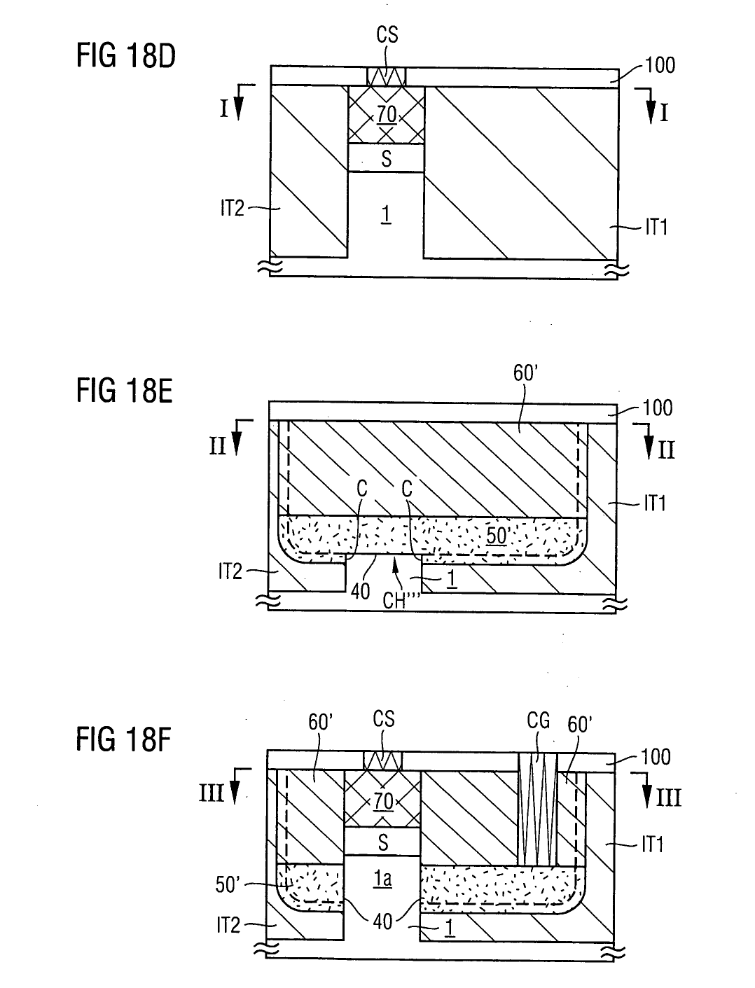

FIGS. 17a)-f) and 18a)-f) show schematic layouts of a manufacturing method for an integrated semiconductor structure according to a fourth embodiment of the present invention.

The third embodiment starts with the process state shown in FIG. 6a)-f), i.e. after partial formation of the gate trench GW′″.

As depicted in FIG. 17a)-f) a silicon oxide etch step is performed subsequent to the process state shown in FIG. 6a)-f) which exposes corners C of the channel CH′″ lying below the gate trench GW′″. For better understanding, in FIGS. 17c), 17e) and 17f) the dashed line illustrates the process state of FIG. 6a)-f), i.e. before the silicon oxide etch step.

The following process steps correspond to process steps described above with respect to FIG. 7a)-f) to FIG. 10a)-f), and a repeated description will be therefore omitted here.

Only shown in FIG. 18a)-f) is the final process state corresponding to the process state of FIG. 10a)-f).

As may be obtained from FIG. 18e), the gate region 50′ which is covered by the oxide layer 60′ covers said exposed corners C of the channel CH′″ lying below the gate trench GW′″, i.e. this transistor exhibits a corner device effect.

Although the present invention has been described with reference to a preferred embodiment, it is not limited thereto, but can be modified in various manners which are obvious for a person skilled in the art. Thus, it is intended that the present invention is only limited by the scope of the claims attached herewith.

1. An integrated circuit including a transistor device comprising:
a semiconductor body;
a pillar formed in said semiconductor body;
a gate trench surrounding said pillar;
a first source/drain region formed in an upper region of said pillar;
a gate dielectric formed on a bottom of said gate trench and surrounding a lower region of said pillar;
a gate formed on said gate dielectric in said gate trench and surrounding the lower region of said pillar; and
at least one second source/drain region formed in an upper region of said semiconductor body adjoining said gate trench.

2. The integrated circuit according to claim 1, further comprising:
a first and second insulation trench filled with a dielectric formed at opposing sides of said pillar;
said gate trench and gate extending into said first and second insulation trench.

3. The integrated circuit according to claim 2, further comprising:
a conductive layer formed on each of said first and second source/drain regions and extending to a same level of height as said first and second insulation trench;
said gate trench being filled with an insulating layer extending to said level of height.

4. The integrated circuit according to claim 2, further comprising:
a gate contact formed on and routed through said insulating layer.

5. The integrated transistor circuit according to claim 2, further comprising:
a first and second source/drain contact formed on said conductive layer.

6. The integrated circuit according to claim 1, wherein a channel formed in the semiconductor body below the gate dielectric has a curved upper surface in a direction perpendicular to a current flow direction.

7. The integrated circuit according to claim 1, wherein said pillar has curved sidewalls.

8. The integrated circuit according to claim 1, wherein a channel formed in the semiconductor body below the gate dielectric includes upper corners covered by said gate dielectric and gate.

9. The integrated according according to claim 1, further comprising:
another second source/drain region formed in an upper region of said semiconductor body adjoining said gate trench at a location opposite to said at least one second source/drain region.

10. A method of manufacturing an integrated transistor device, comprising the steps of:
forming a gate trench in a semiconductor body, thereby defining a pillar in the semiconductor body;
forming a first source/drain region in an upper region of the pillar;
forming a gate dielectric on a bottom of the gate trench and surrounding a lower region of the pillar;
forming a gate on the gate dielectric; and
forming said at least one second source/drain region in an upper region of the semiconductor body adjoining the gate trench.

11. The method according to claim 19, wherein said step of forming another mask stripe comprises the steps of:
depositing a liner layer over said mask;
performing a spacer etch on said liner layer for exposing said scaled down another window in said window;
depositing and etching back said first material so as to form said another mask stripe.

12. The method according to claim 19, wherein said step of forming said gate trench comprises the steps of:
etching back said insulating material in said insulating trenches to a surface of said semiconductor body; and
simultaneously etching back said insulating material in said insulating trenches and said semiconductor body to a depth of said gate trench.

13. The method according to claim 19, wherein said step of forming said gate trench comprises the steps of:
etching back said insulating material in said insulating trenches to a depth of said gate trench; and
etching back said semiconductor body to another depth which is lower than said depth of said gate trench.

14. The method according to claim 19, wherein said step of forming said gate comprises the steps of depositing and etching back a layer of conductive material in said gate trench.

15. The method according to claim 14, wherein after said step of forming said gate, said gate trench is filled with an insulating layer, and thereafter said mask and said insulating layer are etched back.

16. The method according to claim 15, further comprising the steps of:
selectively removing said mask stripe; and depositing and etching back said conductive layer after the first and second source/drain regions are formed.

17. The method according to claim 19, wherein a gate contact is formed on and routed through said insulating layer.

18. The method according to claim 19, wherein a first and second source/drain contact are formed on said conductive layer.

19. The method according to claim 10, further comprising forminq a first and second insulation trench in a semiconductor substrate using a mask stripe of a first material having a thickness of about x and filling said first and second insulation trench with an insulating material to a level corresponding to an upper surface of said mask stripe:
forming a mask of said first material having a thickness of about 2x, said mask having a wind ow which partly exposes said first a nd second insulation trench and said mask stripe.
forming another mask stripe of said first material having a thickness of about x in another window having dimensions scaled down from said window:
etching said mask stripe, mask and another mask stripe by a thickness of about x for exposing said semiconductor body in a first and second window arranged in said wsridow, the first and second windows separated by a part of said mask stripe;

20. An integrated circuit including a transistor, comprising:
a first source/drain portion and a second source/drain portion: and
a first gate electrode disposed adjacent to a substrate portion between the first and second source/drain portions, further comprising a second gate electrode that is in contact with the first electrode, wherein the first and the second gate electrodes are arranged on opposite sides with respect to the first source/drain portion.

21. An integrated circuit including a transistor, comprising:
a first source/drain pardon and a second source/drain portion;
a channel disposed between the first and the second source/drain portions: and
a gate electrode adjacent to the channel
wherein in a cross-sectional view along the channel direction, the gate electrode is adjacent to two opposite sides of the channel.

22. An integrated circuit including first and second transistors, each of the transistors comprising:
a first source/drain portion and a second source/drain portion;
a first gate electrode disposed between the first and the second source/drain portions;
a second gate electrode disposed between the first source/drain portion of the first transistor and the second source/drain portion of the second transistor, wherein the first and second gate electrodes are in contact with each other.
